(19) United States
(12) Patent Application Publication
(10) Pub. No.: US 2026/0162886 A1
(43) Pub. Date: Jun. 11, 2026

(54) THREE-DIMENSIONAL DIFFERENTIAL INDUCTOR WITH VERTICAL WINDING

(71) Applicant: Microchip Technology Inc., Chandler, AZ (US)

(72) Inventors: Mazhar Hoque, Gilbert, AZ (US); Amit Rai, Chandler, AZ (US); Samir Fuke, Tempe, AZ (US); Joseph Rascon, Chandler, AZ (US)

(73) Assignee: Microchip Technology Inc., Chandler, AZ (US)

(21) Appl. No.: 19/197,044

(22) Filed: May 2, 2025

Related U.S. Application Data
(60) Provisional application No. 63/728,349, filed on Dec. 5, 2024.
(60) Provisional application No. 63/770,284, filed on Mar. 11, 2025.
(60) Provisional application No. 63/770,266, filed on Mar. 11, 2025.

(51) Int. Cl. H01F 29/02; H01F 3/04; H01F 21/12; H10D 1/00; H10D 1/68; H10D 86/80; H10D 88/00

(52) U.S. Cl. CPC H01F 29/025; H01F 21/12; H10D 1/041; H10D 1/714; H10D 86/80; H10D 88/01; H01F 3/04

(57) ABSTRACT

A device has a CMOS metal stack of metal layers oriented substantially horizontally in the CMOS metal stack, and a differential inductor coil oriented substantially vertically in the CMOS metal stack and comprising at least two metal layers of the CMOS metal stack. A device having a semiconductor chip having a substrate and an integrated circuit, a metal stack of a plurality of metal layers, wherein the metal stack is connected to the semiconductor chip, and a planar spiral differential inductor comprising at least two metal layers of the metal stack, wherein the semiconductor chip defines a semiconductor plane having a semiconductor plane normal vector and the planar spiral differential inductor defines a differential inductor plane having a differential inductor plane normal vector, wherein an angle between the semiconductor plane normal vector and the differential inductor plane normal vector is between 1 and 90 degrees.

### RELATED PATENT APPLICATIONS

This application claims priority to commonly owned U.S. Provisional Patent Application Nos. 63/770,284 filed Mar. 11, 2025, 63/728,349 filed Dec. 5, 2024 and 63/770,266 filed Mar. 11, 2025, the entire contents of which are hereby incorporated by reference for all purposes.

### TECHNICAL FIELD

The present disclosure relates to CMOS components, in particular, vertically oriented spiral planar differential inductors in CMOS metal stacks.

### BACKGROUND

Conventional approaches to create inductors use large silicon footprints when designing a LC tank or a Balun/transformer. Radio frequency (RF) circuits may use an LC tank or a voltage controlled oscillator (VCO).

The number of metal layers in CMOS metal stacks has been increasing. The availability of ten or more metal layers in smaller technology nodes offer great potential to create useful passive devices.

There is a need for compact, high-density inductors with smaller footprints in CMOS technologies.

### SUMMARY

Aspects provide a device comprising: a CMOS metal stack comprising a plurality of metal layers, wherein the metal layers are oriented substantially horizontally in the CMOS metal stack; and a differential inductor coil oriented substantially vertically in the CMOS metal stack and comprising at least two metal layers of the CMOS metal stack.

According to aspects, there is provided a device comprising: a semiconductor chip comprising a substrate and an integrated circuit; a metal stack comprising a plurality of metal layers, wherein the metal stack is connected to the semiconductor chip; and a first planar spiral differential inductor comprising at least two metal layers of the metal stack, wherein the semiconductor chip defines a semiconductor plane having a semiconductor plane normal vector and the first planar spiral differential inductor defines a first differential inductor plane having a first differential inductor plane normal vector, wherein an angle between the semiconductor plane normal vector and the first differential inductor plane normal vector is between 1 and 90 degrees.

An aspect as in the preceding paragraph provides a device, wherein an angle between the semiconductor plane normal vector and the first differential inductor plane normal vector is 90 degrees.

An aspect as in one of the preceding two paragraphs provides a device, comprising: a second planar spiral differential inductor comprising at least two metal layers of the metal stack.

An aspect as in one of the preceding three paragraphs provides a device, wherein the first planar spiral differential inductor defines a first plane and second planar spiral differential inductor defines a second plane, wherein the first and second planes are substantially parallel.

An aspect as in one of the preceding four paragraphs provides a device, wherein the first planar spiral differential inductor is a primary coil of a transformer and the second planar spiral differential inductor is a secondary coil of the transformer.

An aspect as in one of the preceding five paragraphs provides a device, comprising a MOM capacitor formed in the metal stack and connected with the first planar spiral differential inductor, wherein the MOM capacitor and the first planar spiral differential inductor comprise an inductor capacitor tank.

An aspect as in one of the preceding six paragraphs provides a device, wherein the MOM capacitor and the first planar spiral differential inductor both comprise same metal layer of the metal stack.

An aspect as in one of the preceding seven paragraphs provides a device, wherein the MOM capacitor and the first planar spiral differential inductor comprise different metal layers of the metal stack.

An aspect as in one of the preceding eight paragraphs provides a device, wherein the MOM capacitor defines a MOM capacitor plane and the first planar spiral differential inductor defines a first differential inductor plane, wherein the MOM capacitor plane and the first planar spiral differential inductor plane are the same plane.

An aspect as in one of the preceding nine paragraphs provides a device, wherein the first planar spiral differential inductor comprises a center tap.

According to aspects, there is provided a method comprising: forming a metal stack on a semiconductor chip, wherein the metal stack comprises a plurality of metal layers, wherein the semiconductor chip comprising a substrate and an integrated circuit; forming a first planar spiral differential inductor in the metal stack, wherein the first planar spiral differential inductor comprises at least two metal layers of the metal stack, wherein the semiconductor chip defines a semiconductor plane having a semiconductor plane normal vector and the first planar spiral differential inductor defines a first differential inductor plane having a first differential inductor plane normal vector, wherein an angle between the semiconductor plane normal vector and the first differential inductor plane normal vector is between 1 and 90 degrees.

An aspect as in the preceding paragraph provides a method, wherein forming a metal stack comprises a damascene process.

An aspect as in one of the preceding two paragraphs provides a method, wherein an angle between the semiconductor plane normal vector and the first differential inductor plane normal vector is between 85 and 90 degrees.

An aspect as in one of the preceding three paragraphs provides a method, comprising: forming a second planar spiral differential inductor in the metal stack, wherein the second planar spiral differential inductor comprises at least two metal layers of the metal stack.

An aspect as in one of the preceding four paragraphs provides a method, wherein the first planar spiral differential inductor defines a first plane and second planar spiral differential inductor defines a second plane, wherein the first and second planes are substantially parallel.

An aspect as in one of the preceding five paragraphs provides a method, comprising forming a transformer in the metal stack, wherein the first planar spiral differential inductor is a primary coil of the transformer and the second planar spiral differential inductor is a secondary coil of the transformer.

An aspect as in one of the preceding six paragraphs provides a method, comprising: forming a MOM capacitor in the metal stack; connecting the first planar spiral differential inductor and the MOM capacitor; and forming an inductor capacitor tank comprising the MOM capacitor and the first planar spiral differential inductor.

An aspect as in one of the preceding seven paragraphs provides a method, wherein the MOM capacitor and the first planar spiral differential inductor both comprise same metal layer of the metal stack.

An aspect as in one of the preceding eight paragraphs provides a method, wherein the MOM capacitor and the first planar spiral differential inductor comprise different metal layers of the metal stack.

An aspect as in one of the preceding nine paragraphs provides a method, wherein the MOM capacitor defines a MOM capacitor plane and the first planar spiral differential inductor defines a first differential inductor plane, wherein the MOM capacitor plane and the first differential inductor plane are the same plane.

An aspect as in one of the preceding ten paragraphs provides a method, wherein forming a first planar spiral differential inductor comprises forming a center tap.

According to an aspect, there is provided a semiconductor device comprising a planar spiral differential inductor in a metal stack, and made by a process, the process comprising: forming the metal stack on a semiconductor chip, wherein the metal stack comprises a plurality of metal layers, wherein the semiconductor chip comprising a substrate and an integrated circuit; and forming the planar spiral differential inductor in the metal stack, wherein the planar spiral differential inductor comprises at least two metal layers of the metal stack, wherein the semiconductor chip defines a semiconductor plane having a semiconductor plane normal vector and the first planar spiral differential inductor defines a first planar spiral differential inductor plane having a first differential inductor plane normal vector, wherein an angle between the semiconductor plane normal vector and the first planar spiral differential inductor plane normal vector is between 1 and 90 degrees.

### BRIEF DESCRIPTION OF THE DRAWINGS

A more complete understanding of the disclosure and the advantages thereof may be acquired by referring to the following description, taken in conjunction with the accompanying drawings and wherein:

FIG. 1 shows a top view of a conventional inductor layout, wherein the coil lies in a horizontal plane of a complementary metal-oxide-semiconductor (CMOS) metal stack and is formed by a single layer of metal in the metal stack.

FIG. 2 shows a top view of an inductor with a planar spiral layout, wherein the coil lies in a vertical plane of a complementary metal-oxide-semiconductor (CMOS) metal stack and is formed by multiple layers of metal in the metal stack.

FIGS. 3A-3E show cross-sectional side views of a CMOS semiconductor chip during a front-end process of metallization, which connects semiconductor devices using metal lines and vias in metal layers of a metal stack.

FIGS. 4A-4C show a CMOS metalized semiconductor, wherein a front-end process of metallization has applied metal layers and via layers, which form a metal stack applied to a semiconductor device.

FIG. 5 shows a perspective view of a vertically oriented high density three-dimensional inductor.

FIG. 6 shows a perspective view of two vertically oriented high density three-dimensional inductor windings, wherein the windings are laterally offset from one another and are connected in series.

FIG. 7A shows a perspective view of a plurality of vertically oriented high density three-dimensional inductor windings, wherein the windings are laterally offset from one another and are connected in series. FIG. 7B shows a schematic representation of the plurality of the vertically oriented high density three-dimensional inductor windings shown in FIG. 7A.

FIG. 8A shows a perspective view of a plurality of vertically oriented high density three-dimensional inductor windings, wherein the windings are laterally offset from one another and are connected in series. FIG. 8B shows a schematic representation of the plurality of vertically oriented high density three-dimensional inductor windings shown in FIG. 8A.

FIG. 9A shows a perspective view of seventeen vertically oriented high density three-dimensional inductor windings, wherein the windings are laterally offset from one another and are connected in series in a radial or coiled shape within a metal stack. FIG. 9B shows a schematic representation of the plurality of vertically oriented high density three-dimensional inductor windings shown in FIG. 9A.

FIGS. 10A and 10B show top and perspective views, respectively, of a high density three-dimensional transformer/Balun, wherein a primary coil and a secondary coil are formed in the same metal and via layers of a CMOS metal stack.

FIGS. 11A and 11B show top and perspective views, respectively, of a high density three-dimensional inductor capacitor (LC) tank.

FIGS. 12A and 12B show top and perspective views, respectively, of a high density three-dimensional inductor capacitor (LC) tank, wherein the inductor and a MOM capacitor lie in the same vertical plane of a CMOS metal stack.

FIGS. 13A and 13B show top and perspective views, respectively, of a high density three-dimensional inductor capacitor (LC) tank, wherein an inductor and a MOM capacitor lie in different vertically oriented planes of a CMOS metal stack.

FIG. 14A shows a front view of a differential inductor in a metal stack. FIG. 14B shows a perspective view of the differential inductor shown in FIG. 14A.

FIGS. 15A-15E show a CMOS metalized semiconductor, wherein a front-end process of metallization has applied metal layers and via layers, which form a differential inductor in a metal stack.

FIG. 16 shows a perspective view of a differential inductor vertically oriented in a metal stack of a semiconductor package (not shown).

FIG. 17 shows a perspective view of a differential inductor vertically oriented in a metal stack of a semiconductor package (not shown).

FIG. 18 shows a perspective view of a differential inductor vertically oriented in a metal stack of a semiconductor package (not shown).

FIG. 19 shows a perspective view of a differential inductor having a center tap and vertically oriented in a metal stack of a semiconductor package (not shown).

FIGS. 20A and 20B show top and perspective views, respectively, of a high density three-dimensional differential inductor capacitor (LC) tank in a metal stack.

FIGS. 21A and 121B show top and perspective views, respectively, of a high density three-dimensional differential inductor capacitor (LC) tank in a metal stack.

FIGS. 22A and 22B show top and perspective views, respectively, of a vertically oriented inductor having a magnetic core through the center of the inductor.

FIG. 23A shows a perspective view of a plurality of vertically oriented high density three-dimensional inductor windings with a magnetic core. FIG. 23B shows a schematic representation of the plurality of vertically oriented high density three-dimensional inductor windings and magnetic core shown in FIG. 23A.

FIG. 24A shows a perspective view of seventeen vertically oriented high density three-dimensional inductor windings and a magnetic core. FIG. 24B shows a schematic representation of the plurality of vertically oriented high density three-dimensional inductor windings and magnetic core shown in FIG. 24A.

FIGS. 25A and 25B show top and perspective views, respectively, of a high density three-dimensional transformer/Balun with a magnetic core.

FIGS. 26A and 26B show top and perspective views, respectively, of a high density three-dimensional inductor capacitor (LC) tank having a magnetic core in the inductor.

FIGS. 27A and 27B show top and perspective views, respectively, of a high density three-dimensional inductor capacitor (LC) tank having a magnetic core in the inductor.

The drawings accompanying and forming part of this specification are included to depict certain aspects of the disclosure. The reference number for any illustrated element that appears in multiple different figures has the same meaning across the multiple figures, and the mention or discussion herein of any illustrated element in the context of any particular figure also applies to each other figure, if any, in which that same illustrated element is shown. The features illustrated in the drawings are not necessarily drawn to scale. It should be noted that the features illustrated in the drawings are not necessarily drawn to scale.

### DESCRIPTION

According to aspects, there is provided using the standard metal stacks to create vertical winding of differential inductors instead of the conventional lateral winding. Vertically wound differential inductors may be used in RF circuits with LC tank or VCO (voltage controlled oscillator). Aspects use the availability of a large number of metal layers in advanced process technology nodes to create three-dimensional differential inductors with smaller footprints. Use of vertical winding allows forming the differential inductor coil vertically, which may reduce the silicon area significantly.

The number of metal layers in the CMOS metal stacks has been increasing. The availability of ten or more metal layers in smaller technology nodes offer potential to create useful passive devices. Aspects use the availability of a large number of metal layers in advanced process technology nodes to create three-dimensional differential inductors with smaller footprint.

Aspects use the standard metal stacks to create vertical winding of differential inductors instead of the conventional lateral winding. Therefore, aspects do not change standard fabrication process because the windings of the vertical windings may be made in standard metal layers by standard fabrication processes.

An individual turn or winding of the differential inductor may comprise a top metal segment, a bottom metal segment, and two via stacks, one at opposite ends, to connect the top and bottom metal segments. Subsequent inner turns or windings at the top may use one level lower than the previous top metal and one metal level higher than the previous bottom metal at the bottom.

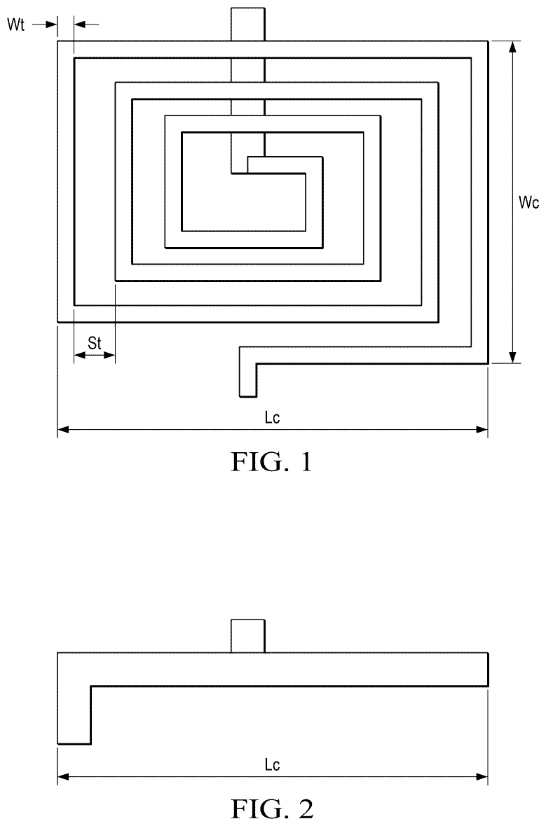

FIG. 1 shows a top view of a conventional inductor layout, wherein the coil lies in a horizontal plane of a complementary metal-oxide-semiconductor (CMOS) metal stack and is formed by a single layer of metal in the metal stack. As shown, this inductor winding has 3.5 turns. In this disclosure, the described semiconductors are assumed to be positioned in a horizonal or lateral plane. Metal layers and via layers, which form a metal stack on the semiconductor (not shown) are also assumed to be positioned in horizontal or lateral planes. The inductor shown in FIG. 1 lies completely in a single metal horizontal or lateral layer and is a lateral winding.

FIG. 2 shows a top view of an inductor with a planar spiral layout, wherein the coil lies in a vertical plane of a complementary metal-oxide-semiconductor (CMOS) metal stack and is formed by multiple layers of metal in the metal stack. This is a vertical winding. In this disclosure, the complimentary metal-oxide-semiconductor (CMOS) (not shown) devices are assumed to be positioned in a horizonal or lateral plane. The inductor shown in FIG. 2 (top view) is “vertically oriented” because it lies in a plane that has a vertical component relative to a horizontally or laterally oriented complimentary metal-oxide-semiconductor (CMOS) devices.

Vertically oriented inductors may be in a plane angled relative to the semiconductor device or chip positioned in a horizontal plane. For example, inductors with a planar spiral layout may be in a plane angled between 1 degree and 90 degrees relative to the semiconductor device positioned in a horizontal plane. In this disclosure, the term “vertically oriented” means angled between 1 degree and 90 degrees relative to a semiconductor device. The semiconductor chip defines a semiconductor plane having a semiconductor plane normal vector and the first inductor defines a first inductor plane having a first inductor plane normal vector. When vertically oriented, an angle between the semiconductor plane normal vector and the first inductor plane normal vector is between 1 and 90 degrees.

The width of the coil (Wc) may be limited by the number of metal layers for a single stack. Multiple coil stacks can be added in series. The coil thickness (Wt) may be limited by metal layer thickness. Multiple metal layers can be tied together in one track with sufficient Via connections to increase coil thickness (Wt). The track spacing (St) may be limited by ILD thickness. Metal layer(s) can be skipped between subsequent track lines to increase track spacing (St). The number of coil turns may be limited by the number of metal layers for one coil stack. Multiple coil stacks can be added in series to increase inductance.

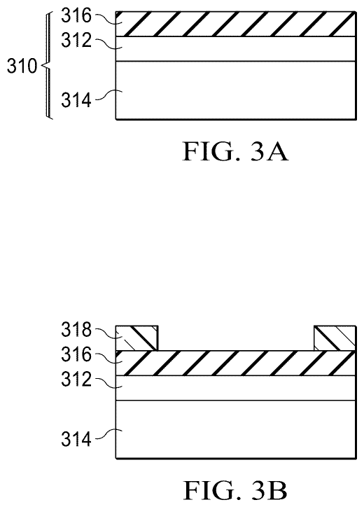

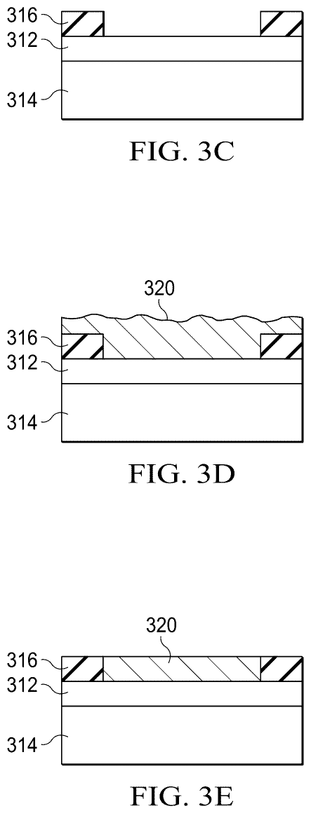

FIGS. 3A-3E show cross-sectional side views of a CMOS semiconductor chip during a front-end process of metallization, which connects semiconductor devices using metal lines and vias in metal layers of a metal stack. In particular, FIGS. 3A-3E show a damascene process for making copper “wires” on top of the circuit of a semiconductor device or chip. The manufacturing flow process starts with a semiconductor device 310 comprising transistors 312 built on a substrate 314. A dielectric 316 is deposited on the semiconductor device 310 as shown in FIG. 3A. As shown in FIG. 3B, a photo resist mask 318 is drawn in a pattern on the dielectric 316. As shown in FIG. 3C, the pattern drawing is etched to remove the exposed portions of the dielectric 316, and the photo resist mask 318 is removed. FIG. 3D shows a copper layer 320 deposited over the dielectric 316. As shown in FIG. 3E, the excess copper is removed via a chemical mechanical planarization (CMP) process that uses physical and chemical reactions to smooth and flatten the surfaces of the copper layer 320 and the dielectric 316. Aluminum “wires” may also be formed.

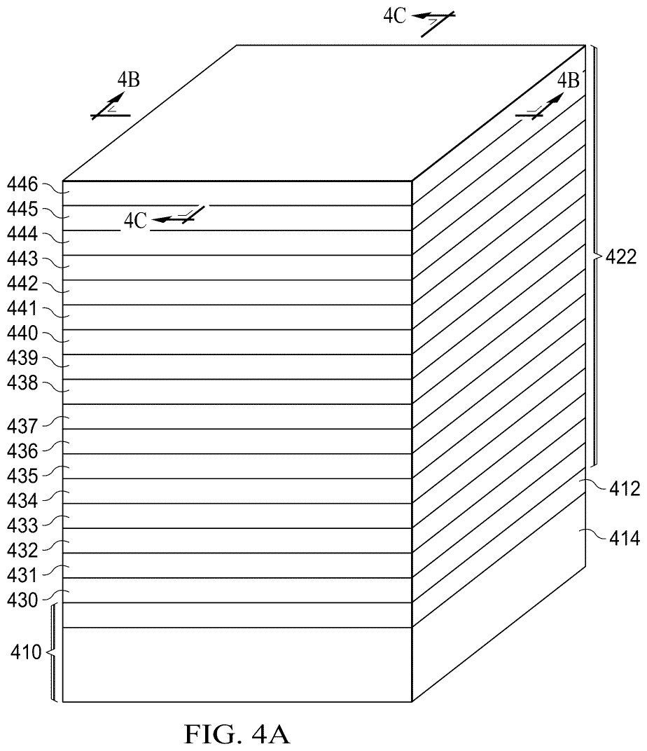

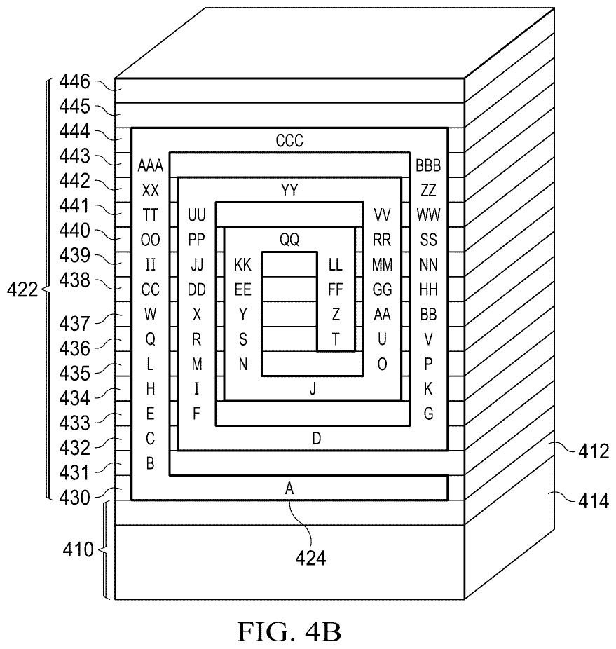

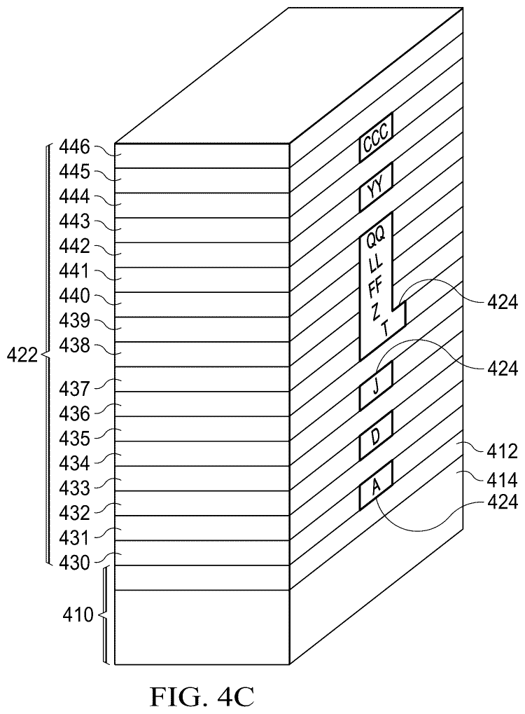

FIGS. 4A-4C show a CMOS metalized semiconductor, wherein a front-end process of metallization has applied metal layers and via layers, which form a metal stack applied to a semiconductor device. FIG. 4A shows a perspective view of the CMOS semiconductor 410 having a metal stack 422. FIG. 4B shows a cross-sectional view of the CMOS metalized semiconductor taken at line B-B, shown in FIG. 4A. FIG. 4C shows a cross-sectional view of the CMOS metalized semiconductor taken at line C-C, shown in FIG. 4A. A metal layer 0 (M0) 430 is applied to the semiconductor device 410. A via layer 0 (V0) 431 is applied to the metal layer 0 (M0) 430. A metal layer 1 (M1) 432 is applied to the via layer 0 (V0) 431. A via layer 1 (V1) 433 is applied to the metal layer 1 (M1) 432. A metal layer 2 (M2) 434 is applied to the via layer 1 (V1) 433. A via layer 2 (V2) 435 is applied to the metal layer 2 (M2) 434. A metal layer 3 (M3) 436 is applied to the via layer 2 (V2) 435. A via layer 3 (V3) 437 is applied to the metal layer 3 (M3) 436. A metal layer 4 (M4) 438 is applied to the via layer 3 (V3) 437. A via layer 4 (V4) 439 is applied to the metal layer 4 (M4) 438. A metal layer 5 (M5) 440 is applied to the via layer 4 (V4) 439. A via layer 5 (V5) 441 is applied to the metal layer 5 (M5) 440. A metal layer 6 (M6) 442 is applied to the via layer 5 (V5) 441. A via layer 6 (V6) 443 is applied to the metal layer 6 (M6) 442. A metal layer 7 (M7) 444 is applied to the via layer 6 (V6) 443. A via layer 7 (V7) 445 is applied to the metal layer 7 (M7) 444. A metal layer 8 (M8) 446 is applied to the via layer 7 (V7) 445. Respective ones of the metal layers and the via layers are applied by a CMOS semiconductor front-end process of metallization similar to that discussed above with reference to FIGS. 3A-3E.

As shown in FIGS. 4B and 4C, the metal stack 422 has an inductor 424 formed across several layers of the metal stack 422. The metal 0 layer (M0) 430 has an inductor horizontal section A. The via 0 layer (V0) 431 has an inductor vertical section B. The metal 1 layer (M1) 432 has an inductor vertical section C and an inductor horizontal section D. The via 1 layer (V1) 433 has inductor vertical sections E, F, and G. The metal 2 layer (M2) 434 has inductor vertical sections H, I, and K and an inductor horizontal section J. The via 2 layer (V2) 435 has inductor vertical sections L, M, N, O, and P. The metal 3 layer (M3) 436 has inductor vertical sections Q, R, S, T, U, and V. The via 3 layer (V3) 437 has inductor vertical sections W, X, Y, Z, AA, and BB. The metal 4 layer (M4) 438 has inductor vertical sections CC, DD, EE, FF, GG, and HH. The via 4 layer (V4) 439 has inductor vertical sections II, JJ, KK, LL, MM, and NN. The metal 5 layer (M5) 440 has inductor vertical sections OO, PP, RR, and SS, and inductor horizontal section QQ. The via 5 layer (V5) 441 has inductor vertical sections TT, UU, VV, and WW. The metal 6 layer (M6) 442 has inductor vertical sections XX and ZZ, and inductor horizontal section YY. The via 6 layer (V6) 443 has inductor vertical sections AAA and BBB. The metal 7 layer (M7) 444 has an inductor horizontal section CCC.

The inductor 424 formed across several layers of the metal stack 422 shown in FIGS. 4B and 4C is oriented to be positioned in a vertically oriented plane relative to the semiconductor device 410 positioned in a horizontal plane.

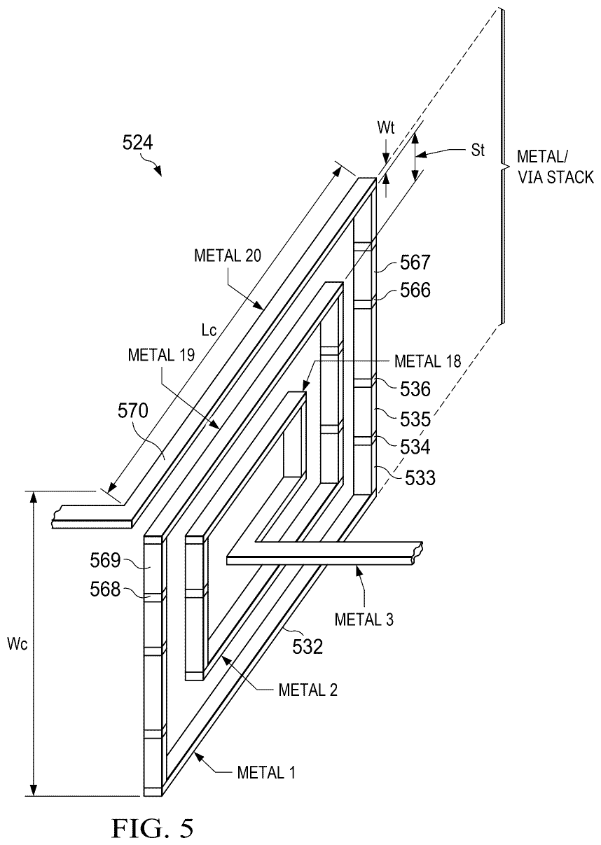

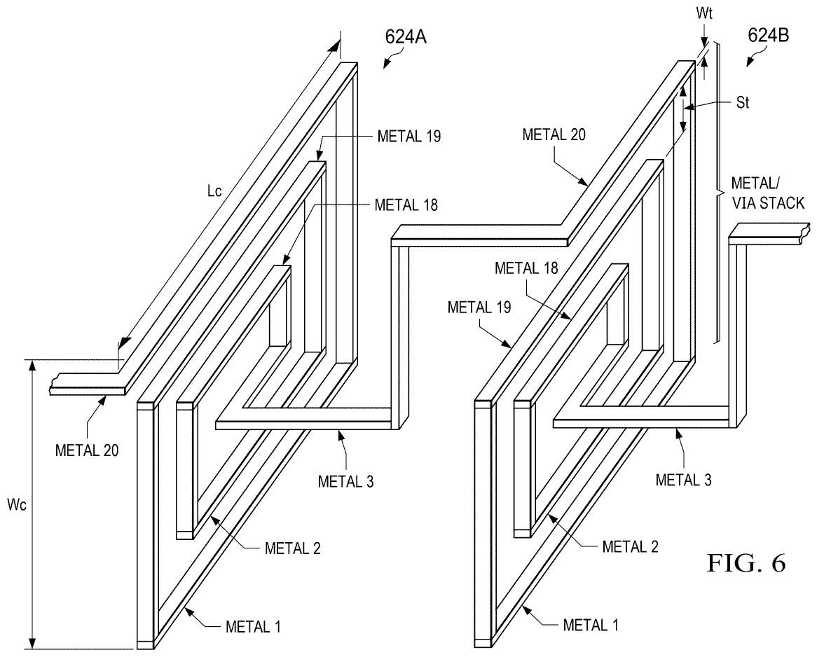

FIG. 5 shows a perspective view of a vertically oriented high density three-dimensional inductor 524. Horizontal portions of the winding are formed by metal 1 layer 532, metal 2 layer 534, metal 3 layer 536, metal 18 layer 566, metal 19 layer 568, and metal 20 layer 570. Vertical portions of the winding are formed by alternating sections of via 1 layer 533, metal 2 layer 534, via 2 layer 535, metal 3 layer 536, via and metal layers, metal 18 layer 566, via 18 layer 567, metal 19 layer 568, and via 19 layer 569. Winding thickness (Wt) may be limited by corresponding metal layer thickness. Multiple metal layers may be tied together with sufficient via connections to form one track to increase the winding thickness Wt. The track spacing St, which is the distance between windings, may be limited by interlayer dielectric ILD thickness. Metal layer(s) can be skipped between subsequent track lines to increase track spacing (St). The number of turns of an inductor coil or winding may be limited by the number of metal layers available in the metal stack. The winding height (Wc) may also be limited by the number of metal layers available in the metal stack. Both of these two limitations can be avoided by adding multiple coils in series to achieve higher inductance.

FIG. 6 shows a perspective view of two vertically oriented high density three-dimensional inductor windings 624A and 624B, wherein the windings are laterally offset from one another and are connected in series. Multiple coil stacks can be added in series or parallel for higher or lower inductance.

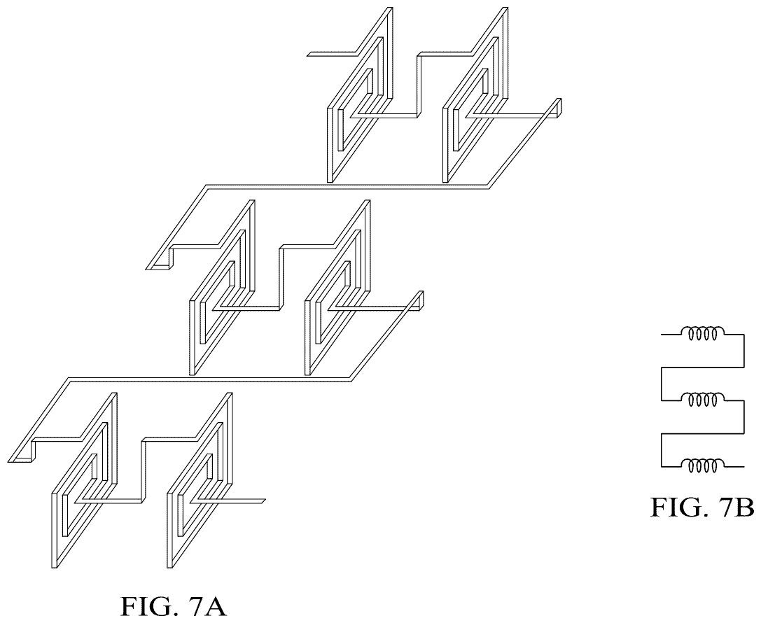

FIG. 7A shows a perspective view of a plurality of vertically oriented high density three-dimensional inductor windings, wherein the windings are laterally offset from one another and are connected in series. In this example, six vertically oriented high density three-dimensional inductor windings are connected in series. The six inductor windings are oriented in the same or parallel planes. FIG. 7B shows a schematic representation of the plurality of the vertically oriented high density three-dimensional inductor windings shown in FIG. 7A.

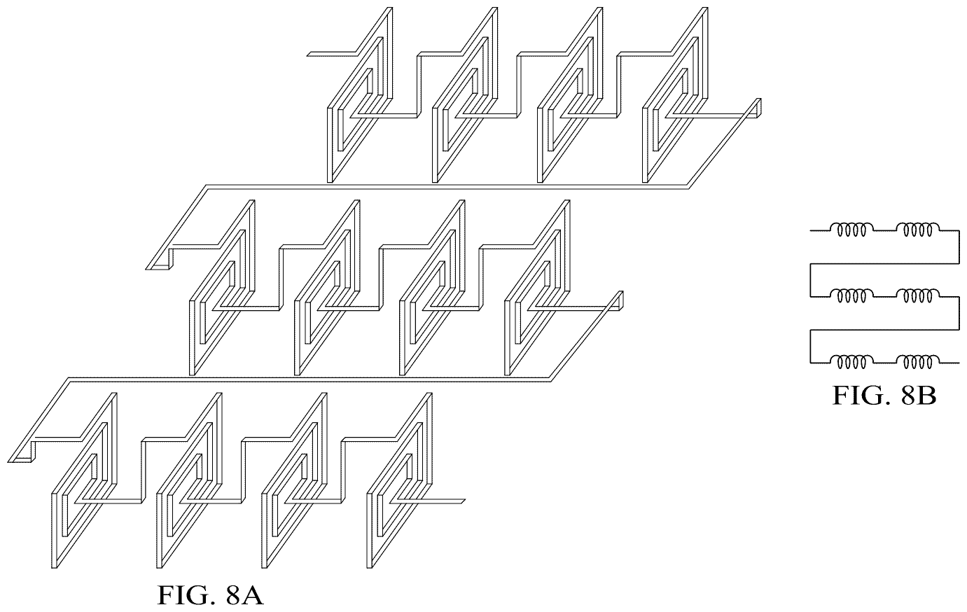

FIG. 8A shows a perspective view of a plurality of vertically oriented high density three-dimensional inductor windings, wherein the windings are laterally offset from one another and are connected in series. In this example, twelve vertically oriented high density three-dimensional inductor windings are connected in series. The twelve inductor windings are oriented in the same or parallel planes. FIG. 8B shows a schematic representation of the plurality of vertically oriented high density three-dimensional inductor windings shown in FIG. 8A.

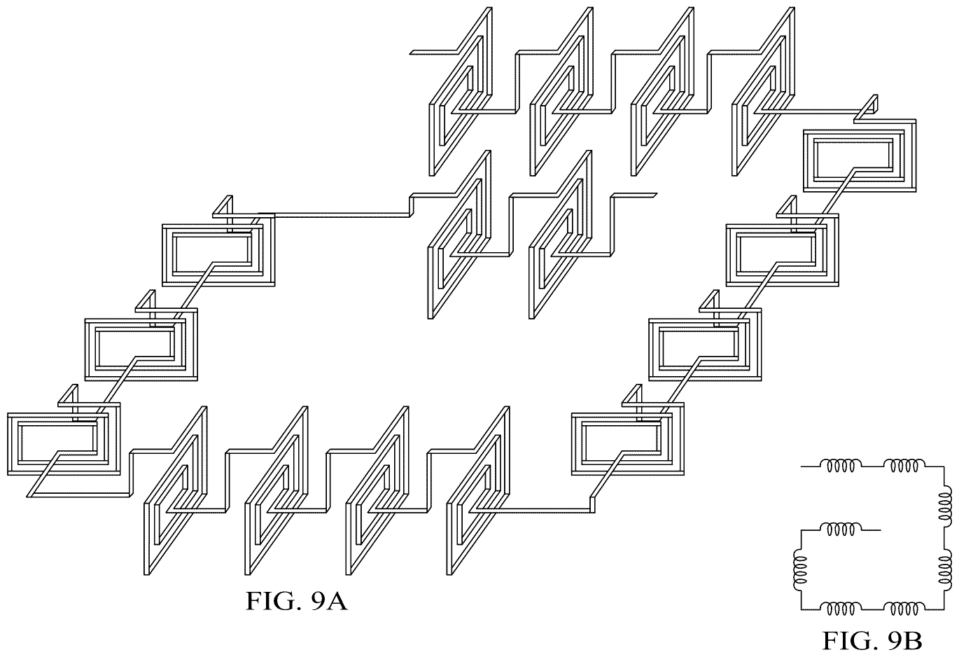

FIG. 9A shows a perspective view of seventeen vertically oriented high density three-dimensional inductor windings, wherein the windings are laterally offset from one another and are connected in series in a radial or coiled shape within a metal stack. In this example, seventeen vertically oriented high density three-dimensional inductor windings are connected in series. Some of the seventeen inductor windings are oriented in the same or parallel planes and others of the seventeen inductor windings are oriented in nonparallel planes. FIG. 9B shows a schematic representation of the plurality of vertically oriented high density three-dimensional inductor windings shown in FIG. 9A.

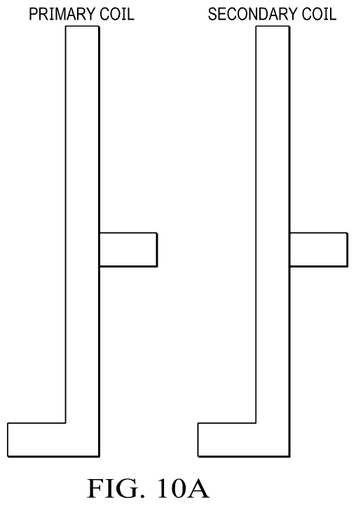

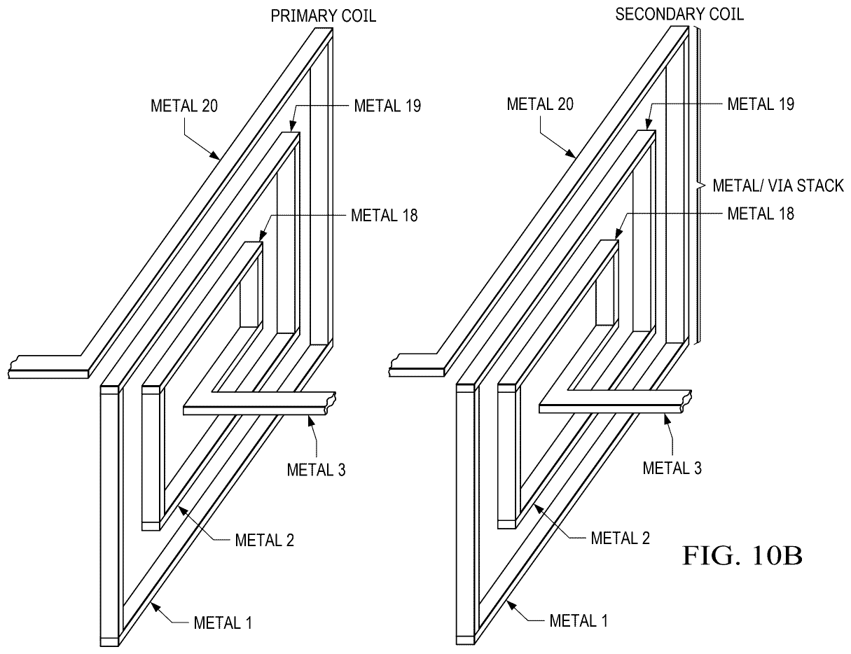

FIGS. 10A and 10B show top and perspective views, respectively, of a high density three-dimensional transformer/Balun, wherein a primary coil and a secondary coil are formed in the same metal and via layers of a CMOS metal stack and are offset laterally from one another. The primary and secondary coils are vertically oriented in a complementary metal-oxide-semiconductor (CMOS) metal stack and are formed by multiple layers of metal in the metal stack. These are vertically oriented windings.

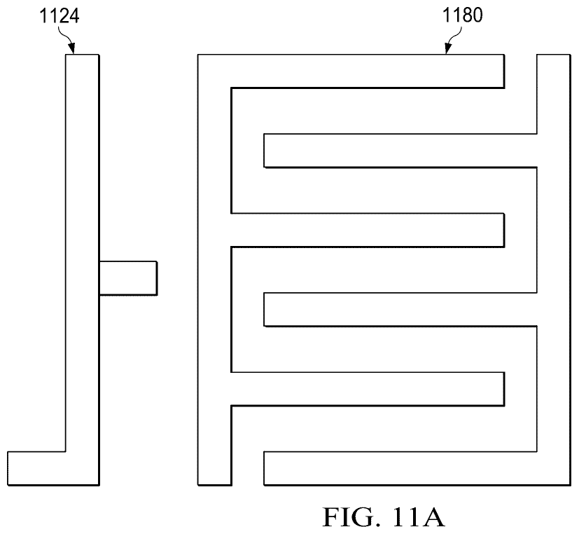

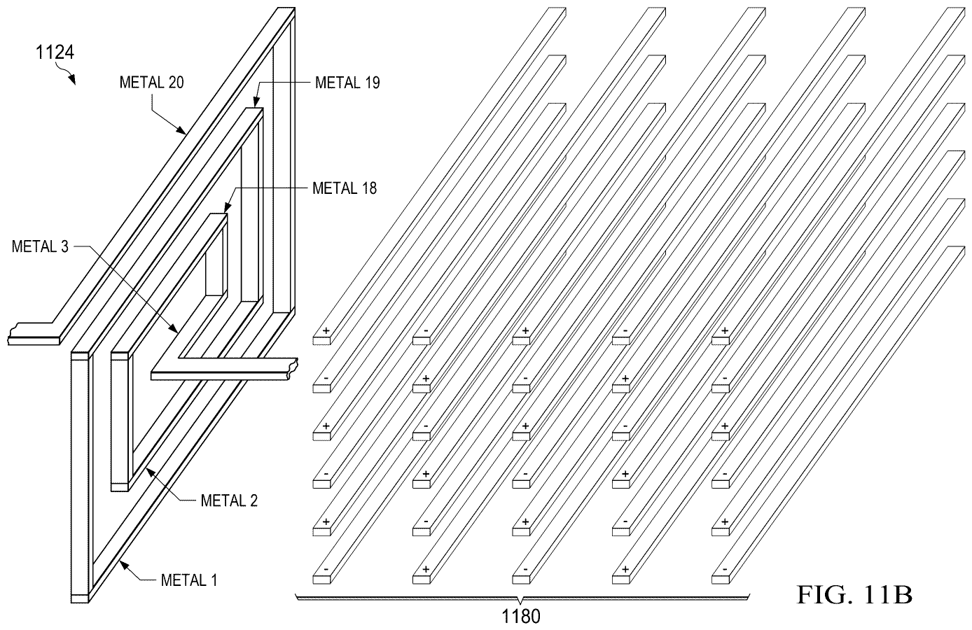

FIGS. 11A and 11B show top and perspective views, respectively, of a high density three-dimensional inductor capacitor (LC) tank. The inductor 1124 lies in a vertical plane of a complementary metal-oxide-semiconductor (CMOS) metal stack and is formed by multiple layers of metal in the metal stack. The MOM capacitor 1180 is three-dimensional and lies in the same complementary metal-oxide-semiconductor (CMOS) metal stack and is formed by multiple layers of metal in the metal stack. The inductor 1124 and the MOM capacitor 1180 are formed in the same metal layers of the CMOS metal stack and are offset laterally from one another.

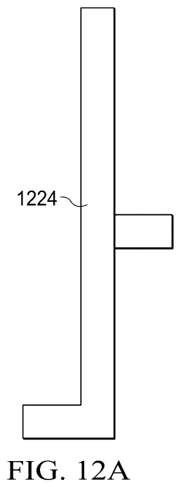

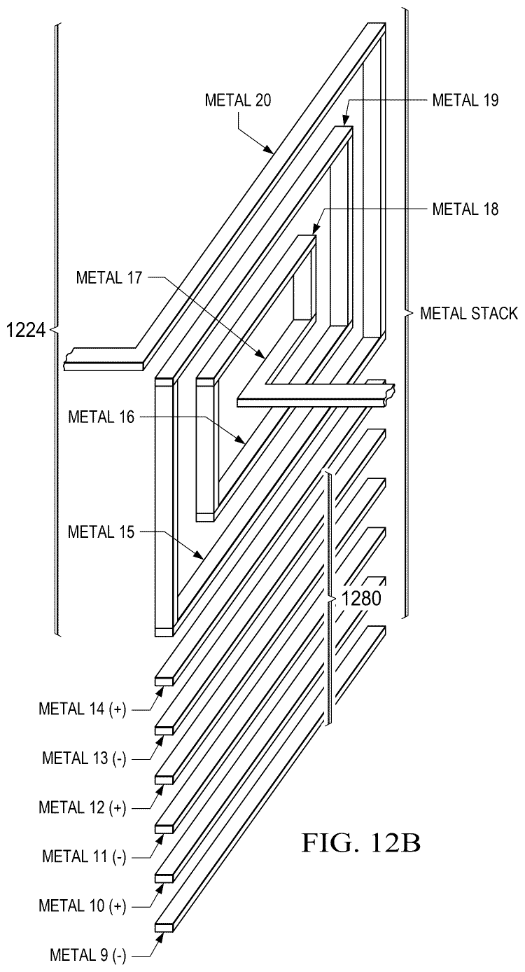

FIGS. 12A and 12B show top and perspective views, respectively, of a high density three-dimensional inductor capacitor (LC) tank of the present disclosure, wherein the inductor 1224 and a MOM capacitor 1280 lie in the same vertical plane of a complementary metal-oxide-semiconductor (CMOS) metal stack and are formed by multiple layers of metal in the metal stack. These are vertical components. The MOM capacitor 1280 is formed in metal layers 9 through 14 of the metal stack and the inductor 1224 is formed in metal layers 15 through 20 of the same metal stack directly above the MOM capacitor 1280 in the same vertically oriented plane. The inductor 1224 may be built with top metals and the MOM capacitor 1280 may be built with bottom metals below a single metal line (or vice versa).

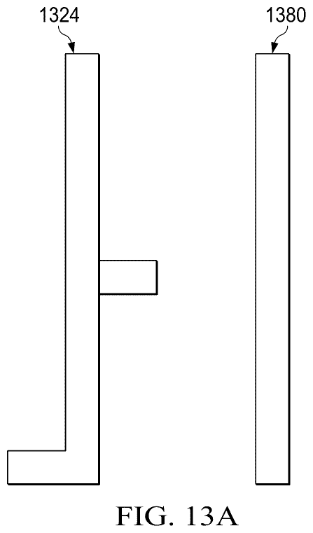

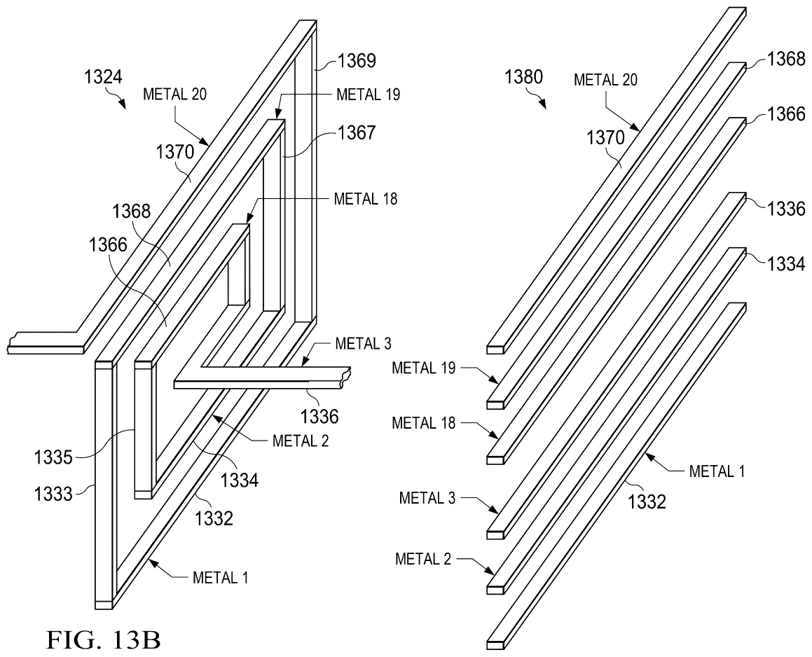

FIGS. 13A and 13B show top and perspective views, respectively, of a high density three-dimensional inductor capacitor (LC) tank. The inductor 1324 and a MOM capacitor 1380 lie in different vertically oriented planes of a complementary metal-oxide-semiconductor (CMOS) metal stack and are formed by multiple layers of metal in the metal stack. These are vertically oriented components. The inductor 1324 and MOM capacitor 1380 are formed in the same metal layers but are positioned laterally offset from one another. Horizontal portions of the inductor 1324 winding are formed by metal 1 layer 1332, metal 2 layer 1334, metal 3 layer 1336, metal 18 layer 1366, metal 19 layer 1368, and metal 20 layer 1370. Vertical portions of the winding are formed by alternating sections of via 1 layer 1333, metal 2 layer 1334, via 2 layer 1335, metal 3 layer 1336, via and metal layers, metal 18 layer 1366, via 18 layer 1367, metal 19 layer 1368, and via 19 layer 1369. Horizontal portions of the MOM capacitor 1380 are formed by metal 1 layer 1332, metal 2 layer 1334, metal 3 layer 1336, via and metal layers, metal 18 layer 1366, metal 19 layer 1368, and metal 20 layer 1370.

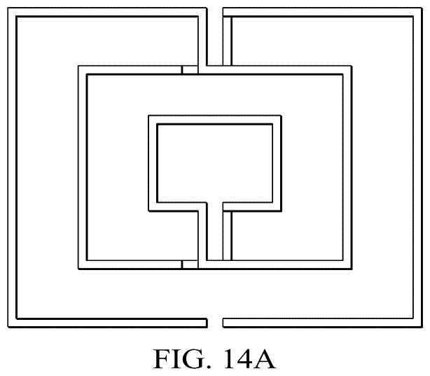

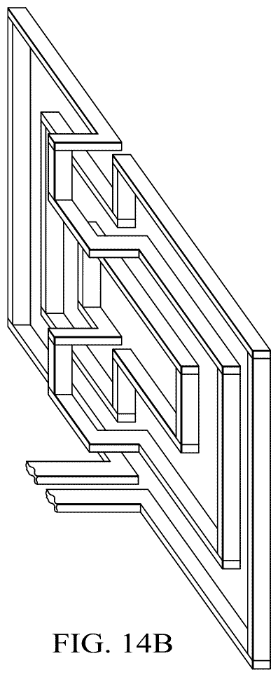

FIG. 14A shows a front view of a differential inductor in a metal stack. FIG. 14B shows a perspective view of the differential inductor shown in FIG. 14A. Wt limited by corresponding metal thickness. Multiple metal layers can be tied together with sufficient via connections to form one track to increase Wt. St may be limited by ILD thickness. Metal layer(s) can be skipped between subsequent track lines to increase track spacing St. The two ends of the differential inductor may be at the bottom metal layer as well. The crossover design may be optimized for desired performance.

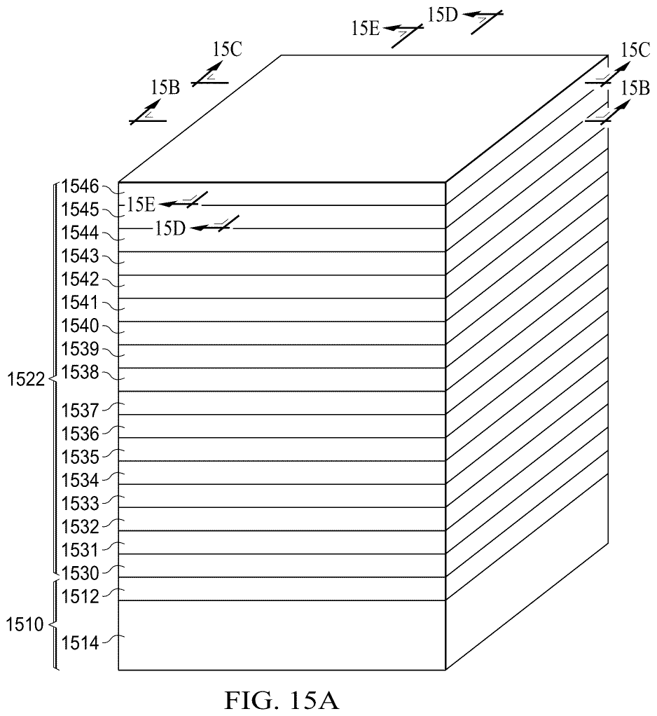

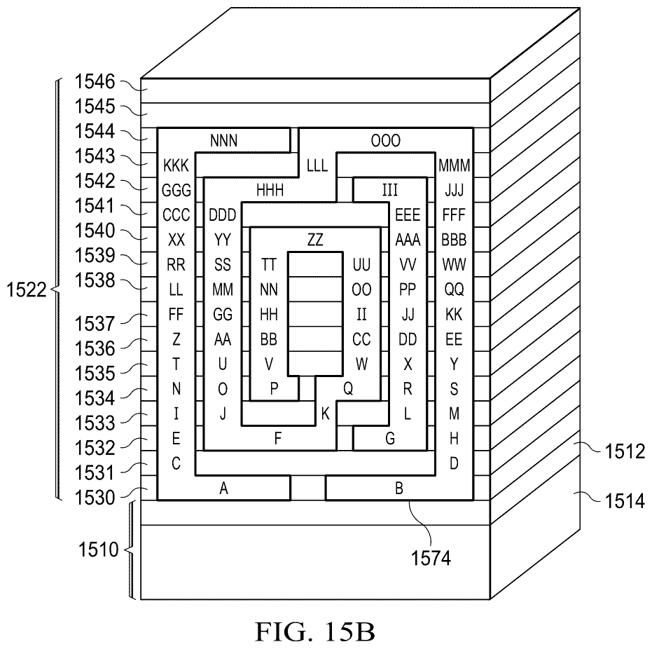

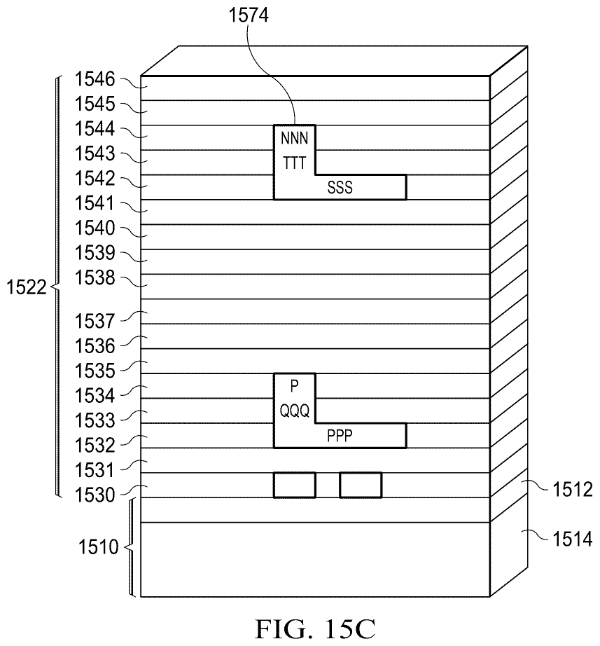

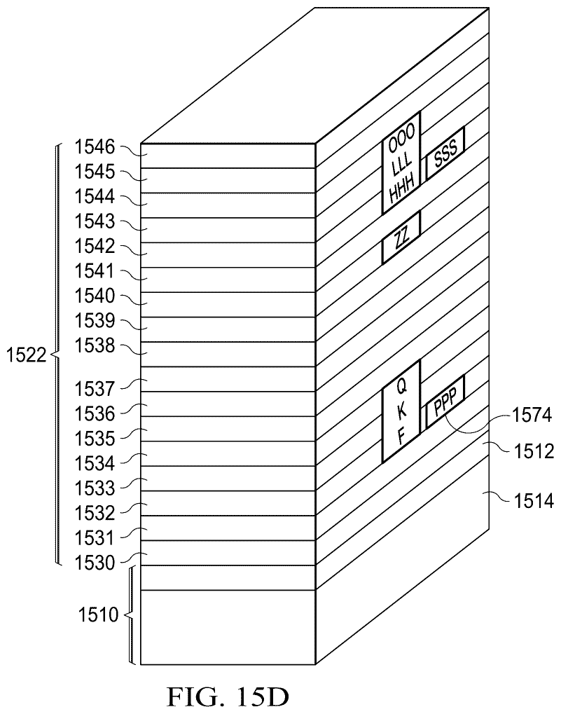

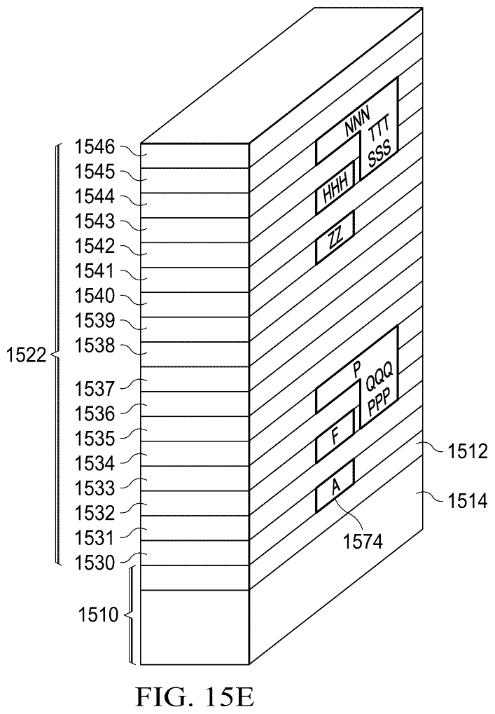

FIGS. 15A-15E show a CMOS metalized semiconductor, wherein a front-end process of metallization has applied metal layers and via layers, which form a metal stack applied to a semiconductor device. FIG. 15A shows a perspective view of the CMOS semiconductor 1510 having a metal stack 1522. FIG. 15B shows a cross-sectional view of the CMOS metalized semiconductor taken at line B-B, shown in FIG. 15A. FIG. 15C shows a cross-sectional view of the CMOS metalized semiconductor taken at line C-C, shown in FIG. 15A. A metal layer 0 (M0) 1530 is applied to the semiconductor device 1510. A via layer 0 (V0) 1531 is applied to the metal layer 0 (M0) 1530. A metal layer 1 (M1) 1532 is applied to the via layer 0 (V0) 1531. A via layer 1 (V1) 1533 is applied to the metal layer 1 (M1) 1532. A metal layer 2 (M2) 1534 is applied to the via layer 1 (V1) 1533. A via layer 2 (V2) 1535 is applied to the metal layer 2 (M2) 1534. A metal layer 3 (M3) 1536 is applied to the via layer 2 (V2) 1535. A via layer 3 (V3) 1537 is applied to the metal layer 3 (M3) 1536. A metal layer 4 (M4) 1538 is applied to the via layer 3 (V3) 1537. A via layer 4 (V4) 1539 is applied to the metal layer 4 (M4) 1538. A metal layer 5 (M5) 1540 is applied to the via layer 4 (V4) 1539. A via layer 5 (V5) 1541 is applied to the metal layer 5 (M5) 1540. A metal layer 6 (M6) 1542 is applied to the via layer 5 (V5) 1541. A via layer 6 (V6) 1543 is applied to the metal layer 6 (M6) 1542. A metal layer 7 (M7) 1544 is applied to the via layer 6 (V6) 1543. A via layer 7 (V7) 1545 is applied to the metal layer 7 (M7) 1544. A metal layer 8 (M8) 1546 is applied to the via layer 7 (V7) 1545. Respective ones of the metal layers and the via layers are applied by a CMOS semiconductor front-end process of metallization similar to that discussed above with reference to FIGS. 3A-3E.

As shown in FIGS. 15B-15D , the metal stack 1522 has a differential inductor 1574 formed across several layers of the metal stack 1522. The metal 0 layer (M0) 1530 has inductor horizontal sections A and B. The via 0 layer (V0) 1531 has differential inductor vertical sections C and D. The metal 1 layer (M1) 1532 has differential inductor vertical sections E and H and differential inductor horizontal sections F and G. The via 1 layer (V1) 1533 has inductor vertical sections I, J, K, L, M, and PPP. The metal 2 layer (M2) 1534 has inductor vertical sections N, O, R, and S and differential inductor horizontal sections P and Q. The via 2 layer (V2) 1535 has differential inductor vertical sections T, U, V, W, X, and Y. The metal 3 layer (M3) 1536 has inductor vertical sections Z, AA, BB, CC, DD, and EE. The via 3 layer (V3) 1537 has inductor vertical sections FF, GG, HH, II, JJ, and KK. The metal 4 layer (M4) 1538 has differential inductor vertical sections LL, MM, NN, OO, PP, and QQ. The via 4 layer (V4) 1539 has differential inductor vertical sections RR, SS, TT, UU, VV, and WW. The metal 5 layer (M5) 1540 has differential inductor vertical sections XX, YY, AAA, and BBB, and differential inductor horizontal section ZZ. The via 5 layer (V5) 1541 has differential inductor vertical sections CCC, DDD, EEE, and FFF. The metal 6 layer (M6) 1542 has differential inductor vertical sections GGG and JJJ, and differential inductor horizontal sections HHH, III, and SSS. The via 6 layer (V6) 1543 has differential inductor vertical sections KKK, LLL, and MMM, and TTT. The metal 7 layer (M7) 1544 has a differential inductor horizontal sections NNN and OOO.

The differential inductor 1574 formed across several layers of the metal stack 1522 shown in FIGS. 15B-15E is oriented to be positioned in a vertically oriented plane relative to the semiconductor device 1510 positioned in a horizontally oriented plane.

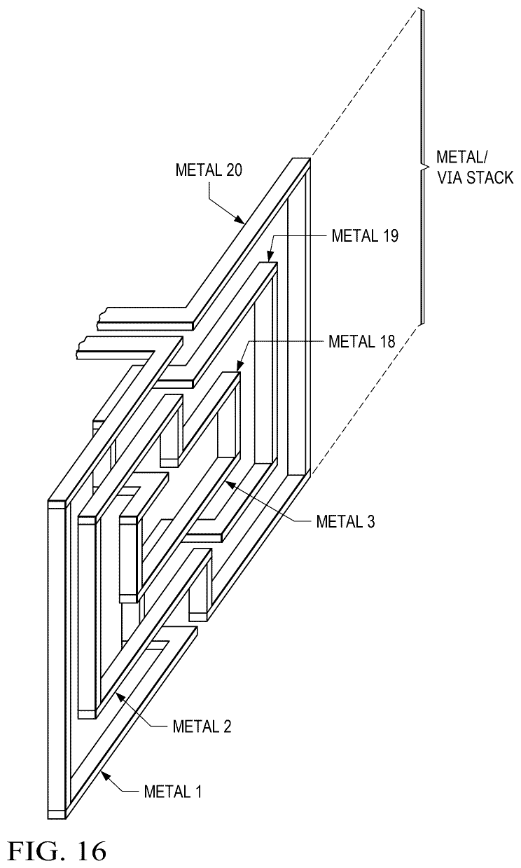

FIG. 16 shows a perspective view of a differential inductor vertically oriented in a metal stack of a semiconductor package (not shown). This design has offset horizontal sections in metal 2 layer (M2) and metal 19 layer (M19). A vertical section connects the offset horizontal section in metal 2 layer (M2) to an L-shaped horizontal section in metal 1 layer (M1). Another vertical section connects the offset horizontal section in metal 19 layer (M19) to an L-shaped horizontal section in metal 18 layer (M18).

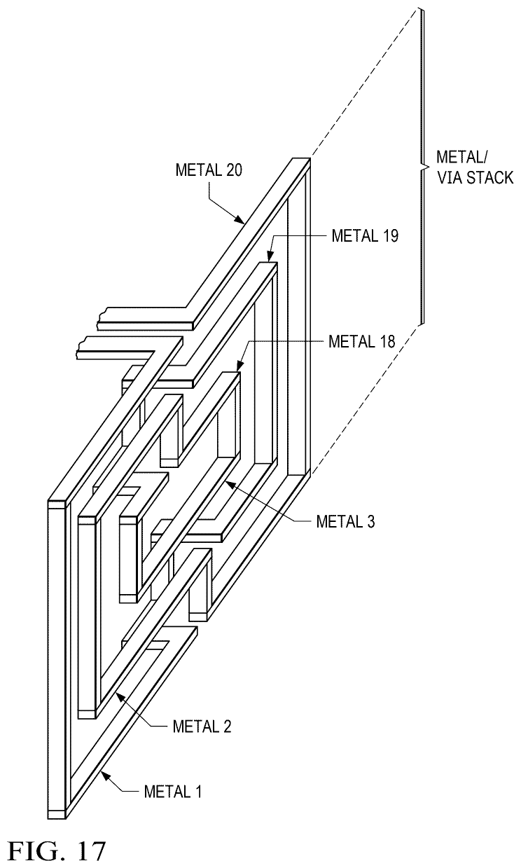

FIG. 17 shows a perspective view of a differential inductor vertically oriented in a metal stack of a semiconductor package (not shown). This design has offset horizontal sections in metal 1 layer (M1) and metal 18 layer (M18). A vertical section connects the offset horizontal section in metal 1 layer (M1) to an L-shaped horizontal section in metal 2 layer (M2). Another vertical section connects the offset horizontal section in metal 18 layer (M18) to an L-shaped horizontal section in metal 19 layer (M19).

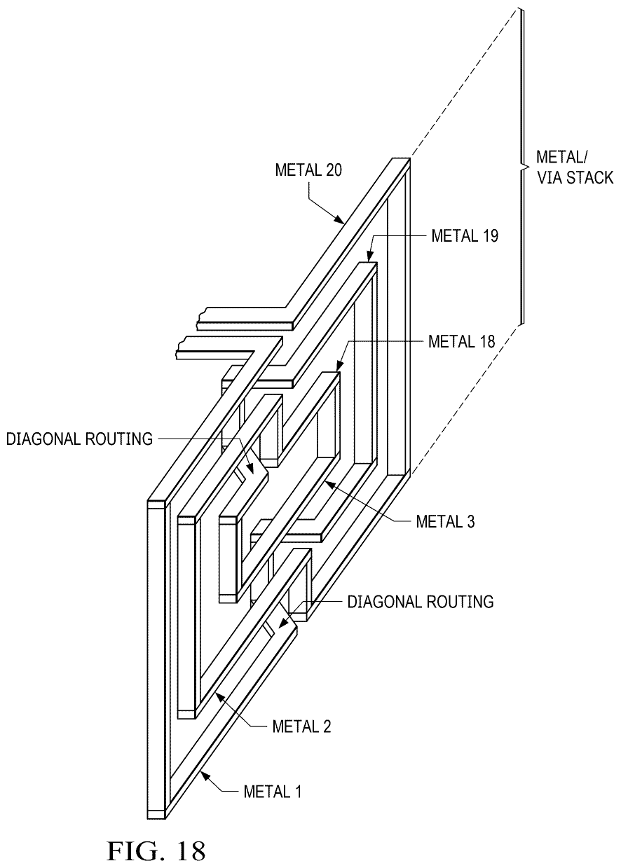

FIG. 18 shows a perspective view of a differential inductor vertically oriented in a metal stack of a semiconductor package (not shown). This design has a diagonal section that connects the horizontal section in metal 1 layer (M1) to an L-shaped horizontal section in metal 2 layer (M2). Another diagonal section connects the horizontal section in metal 18 layer (M18) to an L-shaped horizontal section in metal 19 layer (M19).

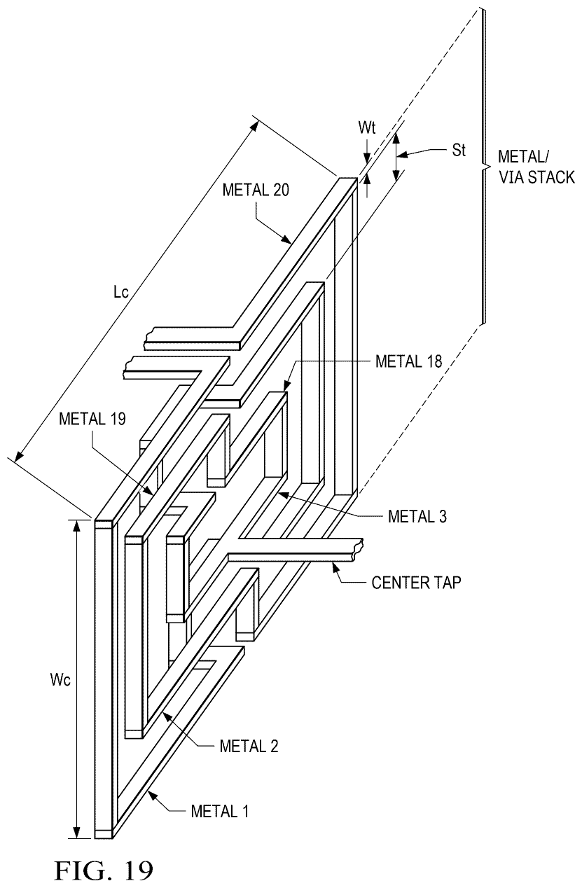

FIG. 19 shows a perspective view of a differential inductor vertically oriented in a metal stack of a semiconductor package (not shown). This differential inductor has a center tap connected to a horizontal section in metal 3 layer (M3).

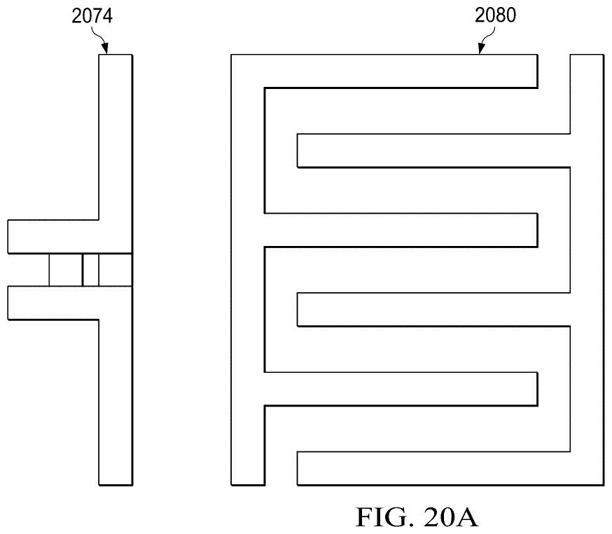

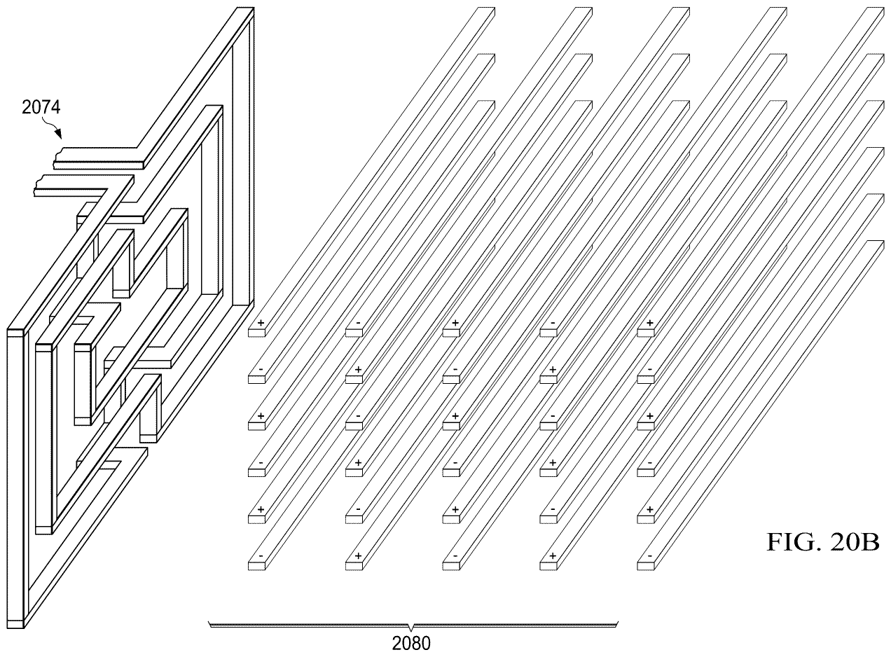

FIGS. 20A and 20B show top and perspective views, respectively, of a high density three-dimensional differential inductor capacitor (LC) tank. The differential inductor 2074 lies in a vertical plane of a complementary metal-oxide-semiconductor (CMOS) metal stack (not shown) and is formed by multiple layers of metal in the metal stack. The MOM capacitor 2080 is three-dimensional and lies in the same complementary metal-oxide-semiconductor (CMOS) metal stack and is formed by multiple layers of metal in the metal stack. The differential inductor 2074 and the MOM capacitor 2080 are formed in the same metal layers of the CMOS metal stack and are offset laterally from one another.

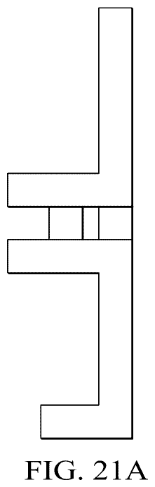

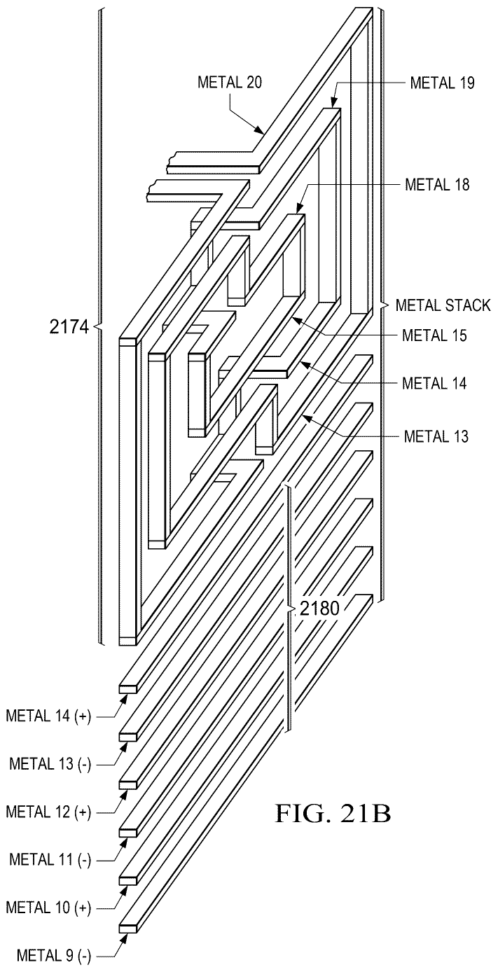

FIGS. 21A and 21B show top and perspective views, respectively, of a high density three-dimensional differential inductor capacitor (LC) tank of the present disclosure, wherein the inductor 2174 and a MOM capacitor 2180 lie in the same vertical plane of a complementary metal-oxide-semiconductor (CMOS) metal stack and are formed by multiple layers of metal in the metal stack. These are vertical components. The MOM capacitor 2180 is formed in metal layers 5 through 10 of the metal stack and the differential inductor 2174 is formed in metal layers 13 through 20 of the same metal stack directly above the MOM capacitor 2180 in the same vertically oriented plane. The differential inductor 2174 may be built with top metals and the MOM capacitor 2180 may be built with bottom metals below a single metal line (or vice versa).

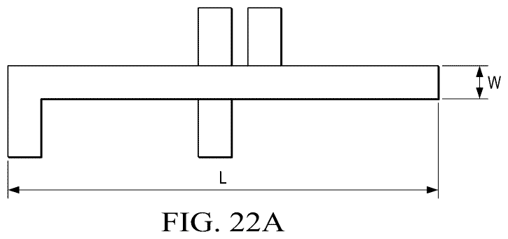

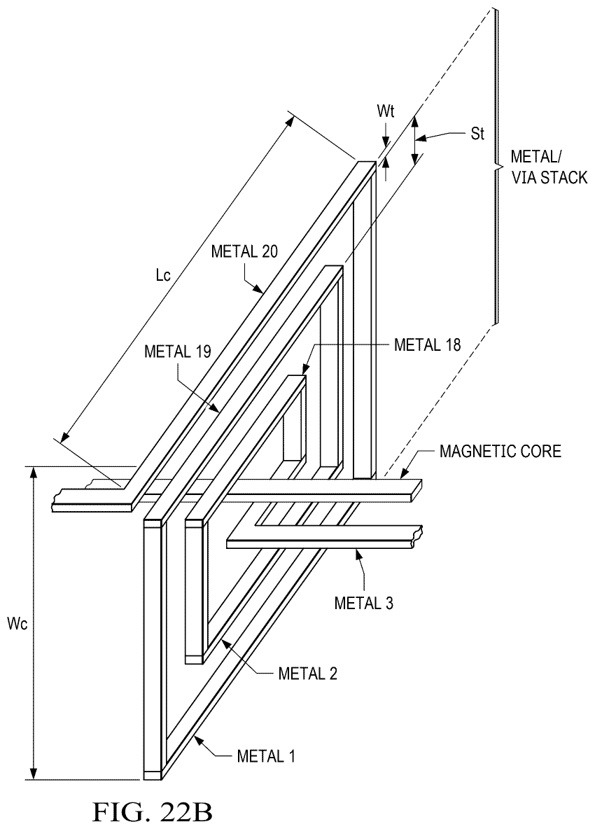

FIGS. 22A and 22B show top and perspective views, respectively, of a vertically oriented inductor having a magnetic core through the center of the inductor. The magnetic core material can be any magnetic material (CoTaZr, Ba3Co2Fe24O41, FeCoXO, FeCoXN, Cr/FeCo/Cr), without limitation. The magnetic material may be integrated into CMOS flow for an integrated inductor with magnetic core. The magnetic core can be a single layer or multi layer stacked together.

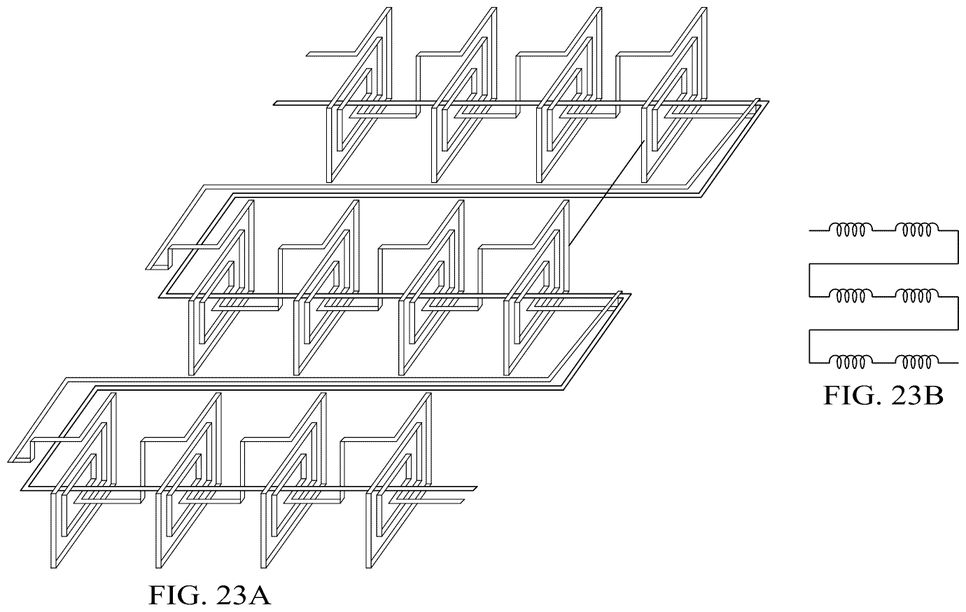

FIG. 23A shows a perspective view of a plurality of vertically oriented high density three-dimensional inductor windings with a magnetic core, wherein the windings are laterally offset from one another and are connected in series. The magnetic core runs through the centers of the inductor windings. In this example, twelve vertically oriented high density three-dimensional inductor windings are connected in series and the magnetic core runs through them in the same series. The twelve inductor windings are oriented in the same or parallel vertically oriented planes and the magnetic core is horizontally oriented. FIG. 23B shows a schematic representation of the plurality of vertically oriented high density three-dimensional inductor windings and magnetic core shown in FIG. 23A.

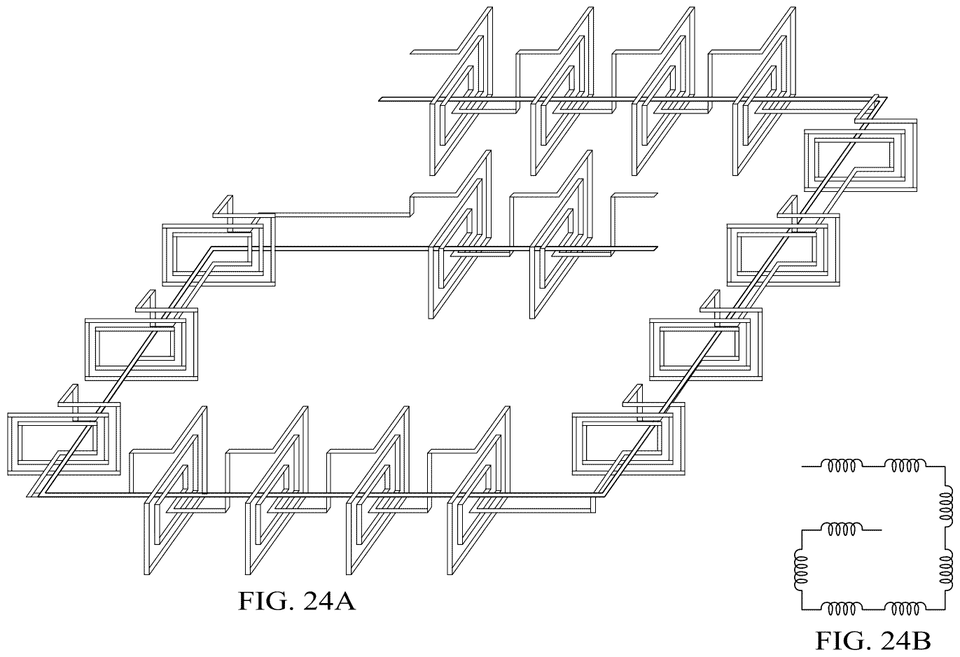

FIG. 24A shows a perspective view of seventeen vertically oriented high density three-dimensional inductor windings and a magnetic core, wherein the windings are laterally offset from one another and are connected in series in a radial or coiled shape within a metal stack. The magnetic core extends through the centers of the inductor windings in a radial or coiled shape within a metal stack. The magnetic core may be in a single layer of the metal stack. In this example, seventeen vertically oriented high density three-dimensional inductor windings are connected in series and the magnetic core extends through them in the same series. Some of the seventeen inductor windings are oriented in the same or parallel planes and others of the seventeen inductor windings are oriented in nonparallel planes. FIG. 24B shows a schematic representation of the plurality of vertically oriented high density three-dimensional inductor windings and magnetic core shown in FIG. 24A.

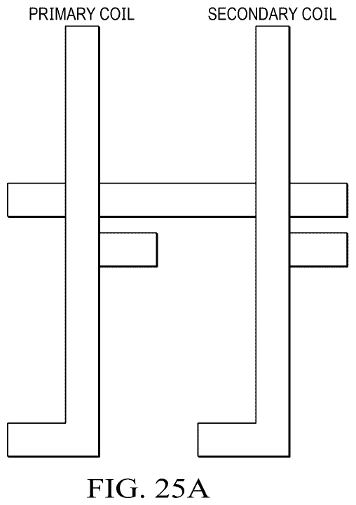

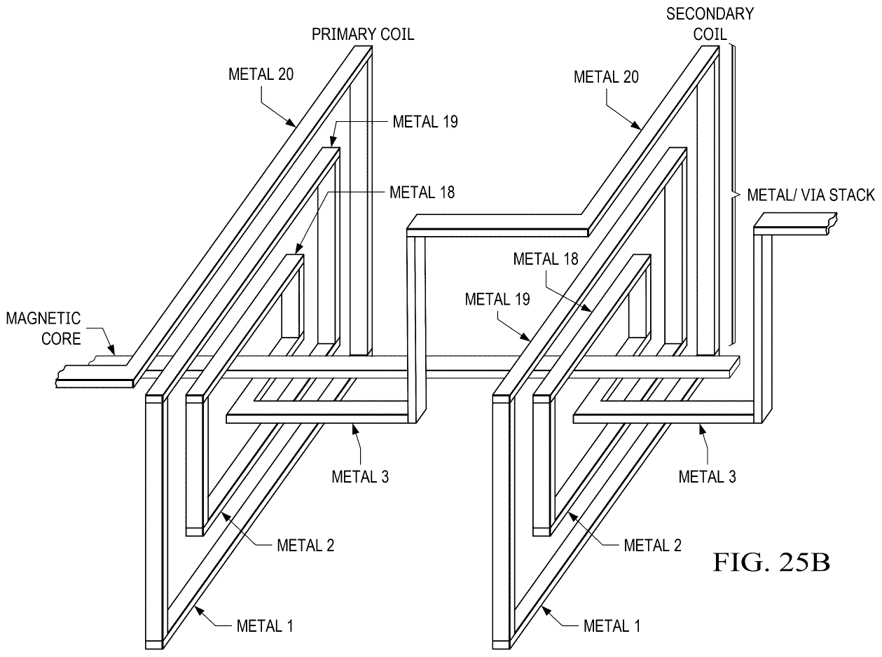

FIGS. 25A and 25B show top and perspective views, respectively, of a high density three-dimensional transformer/Balun with a magnetic core, wherein a primary coil and a secondary coil are formed in the same metal and via layers of a CMOS metal stack and are offset laterally from one another. The magnetic core extends through a single later of the metal stack. The primary and secondary coils are vertically oriented in a complementary metal-oxide-semiconductor (CMOS) metal stack and are formed by multiple layers of metal in the metal stack. These are vertically oriented windings. The magnetic core extends horizontally oriented through a layer of the metal stack.

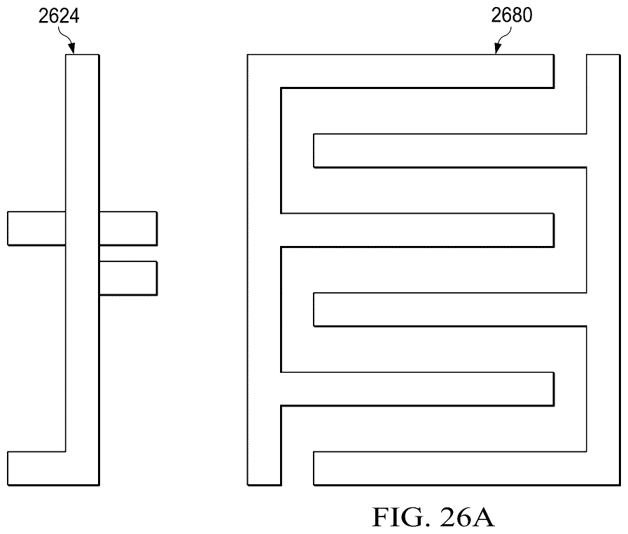

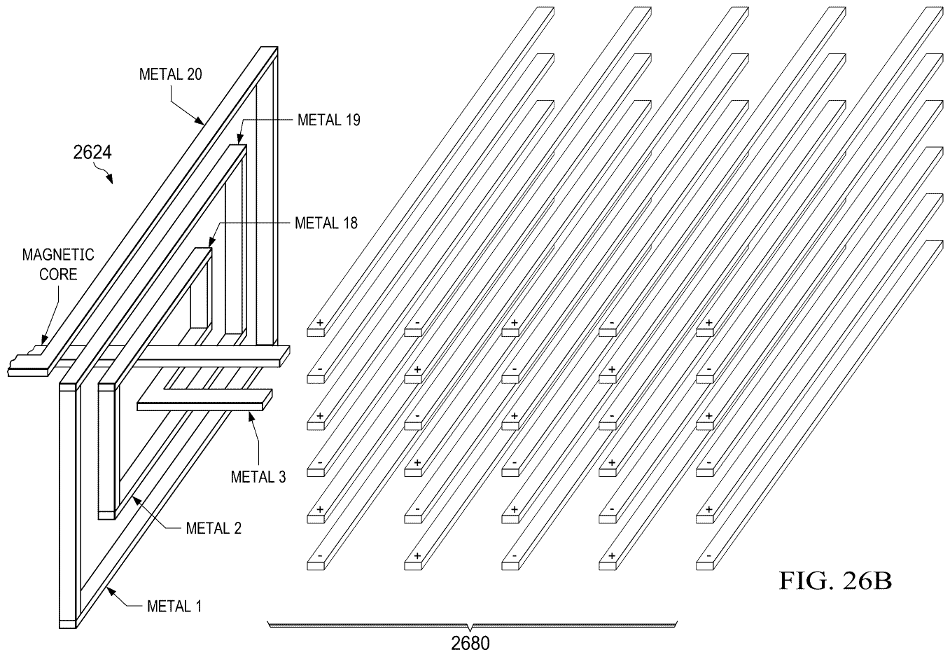

FIGS. 26A and 26B show top and perspective views, respectively, of a high density three-dimensional inductor capacitor (LC) tank having a magnetic core in the inductor. The inductor 2624 lies in a vertical plane of a complementary metal-oxide-semiconductor (CMOS) metal stack and is formed by multiple layers of metal in the metal stack. The magnetic core may extend horizontally oriented in a layer of the metal stack. The MOM capacitor 2680 is three-dimensional and lies in the same complementary metal-oxide-semiconductor (CMOS) metal stack and is formed by multiple layers of metal in the metal stack. The inductor 2624 and the MOM capacitor 1180 are formed in the same metal layers of the CMOS metal stack and are offset laterally from one another. These are vertically oriented components, but the magnetic core is horizontally oriented.

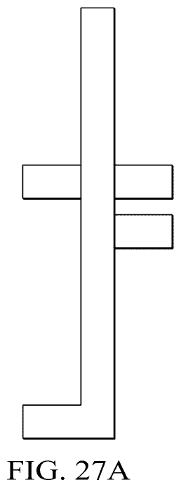

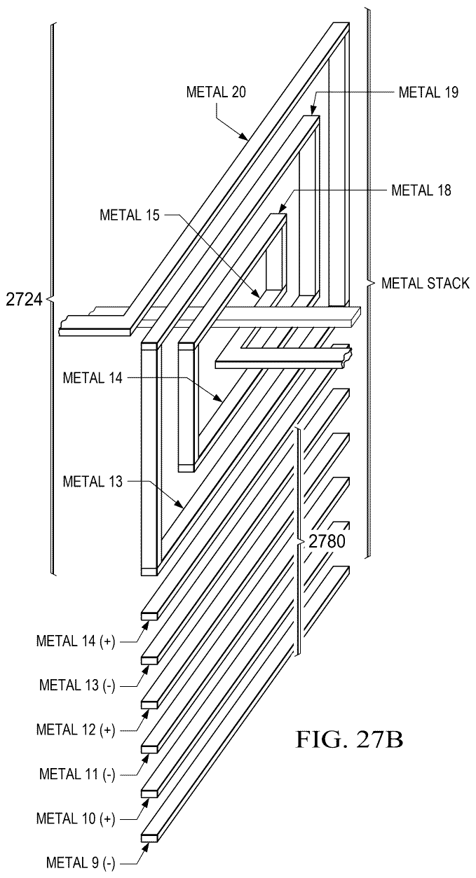

FIGS. 27A and 27B show top and perspective views, respectively, of a high density three-dimensional inductor capacitor (LC) tank of the present disclosure, wherein the inductor 2724 and a MOM capacitor 2780 lie in the same vertical plane of a complementary metal-oxide-semiconductor (CMOS) metal stack and are formed by multiple layers of metal in the metal stack. These are vertical components. The inductor 2724 has a magnetic core extending horizontally oriented through the center of the inductor 2724. The MOM capacitor 2780 is formed in metal layers 5 through 10 of the metal stack. The inductor 2724 is formed in metal layers 13 through 20 of the same metal stack directly above the MOM capacitor 2780 in the same vertically oriented plane. The magnetic core may be formed in metal layer 16 or 17, or a combination of layers 16 and 17. The magnetic core is created at the center of the 3D vertical coil using magnetic material. The inductor 2724 may be built with top metals and the MOM capacitor 2780 may be built with bottom metals below a single metal line (or vice versa).

Although examples have been described above, other variations and examples may be made from this disclosure without departing from the spirit and scope of these disclosed examples.

What is claimed is:

1. A device comprising:
a semiconductor chip comprising a substrate and an integrated circuit;
a metal stack comprising a plurality of metal layers, wherein the metal stack is connected to the semiconductor chip; and
a first planar spiral differential inductor comprising at least two metal layers of the metal stack,
wherein the semiconductor chip defines a semiconductor plane having a semiconductor plane normal vector and the first planar spiral differential inductor defines a first differential inductor plane having a first differential inductor plane normal vector, wherein an angle between the semiconductor plane normal vector and the first differential inductor plane normal vector is between 1 and 90 degrees.

2. The device of claim 1, wherein an angle between the semiconductor plane normal vector and the first differential inductor plane normal vector is between 90 degrees.

3. The device of claim 1, comprising: a second planar spiral differential inductor comprising at least two metal layers of the metal stack.

4. The device of claim 3, wherein the first planar spiral differential inductor defines a first plane and second planar spiral differential inductor defines a second plane, wherein the first and second planes are substantially parallel.

5. The device of claim 3, wherein the first planar spiral differential inductor is a primary coil of a transformer and the second planar spiral differential inductor is a secondary coil of the transformer.

6. The device of claim 1, comprising a MOM capacitor formed in the metal stack and connected with the first planar spiral differential inductor, wherein the MOM capacitor and the first planar spiral differential inductor comprise an inductor capacitor tank.

7. The device of claim 6, wherein the MOM capacitor and the first planar spiral differential inductor both comprise same metal layer of the metal stack.

8. The device of claim 6, wherein the MOM capacitor and the first planar spiral differential inductor comprise different metal layers of the metal stack.

9. The device of claim 6, wherein the MOM capacitor defines a MOM capacitor plane and the first planar spiral differential inductor defines a first differential inductor plane, wherein the MOM capacitor plane and the first planar spiral differential inductor plane are the same plane.

10. The device of claim 1, wherein the first planar spiral differential inductor comprises a center tap.

11. A method comprising:
forming a metal stack on a semiconductor chip, wherein the metal stack comprises a plurality of metal layers, wherein the semiconductor chip comprising a substrate and an integrated circuit;
forming a first planar spiral differential inductor in the metal stack, wherein the first planar spiral differential inductor comprises at least two metal layers of the metal stack.
wherein the semiconductor chip defines a semiconductor plane having a semiconductor plane normal vector and the first planar spiral differential inductor defines a first differential inductor plane having a first differential inductor plane normal vector, wherein an angle between the semiconductor plane normal vector and the first differential inductor plane normal vector is between 1 and 90 degrees.

12. The method of claim 11, wherein forming a metal stack comprises a damascene process.

13. The method of claim 11, wherein an angle between the semiconductor plane normal vector and the first differential inductor plane normal vector is 90 degrees.

14. The method of claim 11, comprising: forming a second planar spiral differential inductor in the metal stack, wherein the second planar spiral differential inductor comprises at least two metal layers of the metal stack.

15. The method of claim 14, wherein the first planar spiral differential inductor defines a first plane and second planar spiral differential inductor defines a second plane, wherein the first and second planes are substantially parallel.

16. The method of claim 14, comprising forming a transformer in the metal stack, wherein the first planar spiral differential inductor is a primary coil of the transformer and the second planar spiral differential inductor is a secondary coil of the transformer.

17. The method of claim 11, comprising:
forming a MOM capacitor in the metal stack;
connecting the first planar spiral differential inductor and the MOM capacitor; and
forming an inductor capacitor tank comprising the MOM capacitor and the first planar spiral differential inductor.

18. The method of claim 17, wherein the MOM capacitor and the first planar spiral differential inductor both comprise same metal layer of the metal stack.

19. The method of claim 17, wherein the MOM capacitor and the first planar spiral differential inductor comprise different metal layers of the metal stack.

20. The method of claim 17, wherein the MOM capacitor defines a MOM capacitor plane and the first planar spiral differential inductor defines a first differential inductor plane, wherein the MOM capacitor plane and the first differential inductor plane are the same plane.

21. The device of claim 11, wherein forming a first planar spiral differential inductor comprises forming a center tap.

22. A semiconductor device comprising a planar spiral differential inductor in a metal stack, and made by a process, the process comprising:
forming the metal stack on a semiconductor chip, wherein the metal stack comprises a plurality of metal layers, wherein the semiconductor chip comprising a substrate and an integrated circuit; and
forming the planar spiral differential inductor in the metal stack, wherein the planar spiral differential inductor comprises at least two metal layers of the metal stack, wherein the semiconductor chip defines a semiconductor plane having a semiconductor plane normal vector and the first planar spiral differential inductor defines a first planar spiral differential inductor plane having a first differential inductor plane normal vector, wherein an angle between the semiconductor plane normal vector and the first planar spiral differential inductor plane normal vector is between 1 and 90 degrees.
